(19) United States
(12) Patent Application Publication
(10) Pub. No.: US 2010/0320548 A1
(43) Pub. Date: Dec. 23, 2010

(54) Silicon-Rich Nitride Etch Stop Layer for Vapor HF Etching in MEMS Device Fabrication

(75) Inventors: Christine H. Tsau, Arlington, MA (US); Thomas Kieran Nunan, Carlisle, MA (US)

Correspondence Address: Sunstein Kann Murphy & Timbers LLP, 125 SUMMER STREET, BOSTON, MA, 02110-1618, US

(73) Assignee: ANALOG DEVICES, INC., Norwood, MA (US)

(21) Appl. No.: 12/813,117

(22) Filed: Jun. 10, 2010

Related U.S. Application Data
(60) Provisional application No. 61/218,268, filed on Jun. 18, 2009.

(51) Int. Cl. H01L 29/84; H01L 21/30; H01L 21/318; H01L 29/06

(52) U.S. Cl. 257/415; 438/50; 438/791; 257/649; 257/E21.293; 257/E29.324; 257/E29.018; 257/E21.211

(57) ABSTRACT

A thin silicon-rich nitride film (e.g., having a thickness in the range of around 100A to 10000A) deposited using low-pressure chemical vapor deposition (LPCVD) is used for etch stop during vapor HF etching in various MEMS wafer fabrication processes and devices. The LPCVD silicon-rich nitride film may replace, or be used in combination with, a LPCVD stoichiometric nitride layer in many existing MEMS fabrication processes and devices. The LPCVD silicon-rich nitride film is deposited at high temperatures (e.g., typically around 650-900 degrees C.). Such a LPCVD silicon-rich nitride film generally has enhanced etch selectivity to vapor HF and other harsh chemical environments compared to stoichiometric silicon nitride and therefore a thinner layer typically can be used as an embedded etch stop layer in various MEMS wafer fabrication processes and devices and particularly for vapor HF etching processes, saving time and money in the fabrication process.

### CROSS-REFERENCE TO RELATED APPLICATION(S)

This patent application claims the benefit of U.S. Provisional Patent Application No. 61/218,268 filed Jun. 18, 2009, which is hereby incorporated herein by reference in its entirety.

This patent application also may be related to U.S. Provisional Patent Application No. 61/218,283 entitled SILICON CARBIDE FOR ETCH STOP AND PASSIVATION IN MEMS WAFER FABRICATION filed on Jun. 18, 2009 (Attorney Docket No. 2550/C50), which is hereby incorporated herein by reference in its entirety.

### FIELD OF THE INVENTION

The present invention relates generally to MEMS wafer fabrication and more particularly to etch stop for vapor HF etching in MEMS wafer fabrication.

### BACKGROUND OF THE INVENTION

Microelectromechanical systems (MEMS) devices including such things as inertial sensors (e.g., capacitive, piezoelectric, and convective accelerometers and vibratory and tuning fork gyroscopes), microphones, pressure sensors, RF devices, and optical devices (e.g., optical switches) often include a number of structures that are released so as to be movable. Examples of released structures include microphone diaphragms, inertial sensor proof masses and shuttles, and suspended encapsulation layer(s) that cap sensor structures.

MEMS devices are typically formed on a substrate (e.g., a silicon or silicon-on-insulator wafer) using various micromachining techniques such as etching into the substrate and/or depositing/patterning various materials. Structures to be released are typically formed on top of one or more “sacrificial” layers of materials that are subsequently removed to release the structure. Typical sacrificial layers for MEMS wafer fabrication include an oxide layer formed on a nitride layer (e.g., stoichiometric silicon nitride formed using low-pressure chemical vapor deposition), where the nitride layer also acts as an etch stop layer during removal of the oxide layer. The oxide layer is typically removed using a wet or dry etch process. A wet etch process (e.g., buffered oxide etch) typically requires releasing holes that are carefully placed and spaced to allow for wet etch access, which can impose certain constraints on product design and processes. A dry etch process (e.g., vapor HF) generally provides more freedom in the placement and spacing of etch holes which in turn can lead to more flexibility in the sensor design. Unfortunately, stoichiometric silicon nitride generally has poor etch selectivity to vapor HF.

Similarly, it is often the case that certain structures (releasable or otherwise) need to be protected during and/or after MEMS wafer fabrication, for example, for electrical passivation in the fully formed device, as a top passivation layer in the fully formed device, for passivation during release of a releasable structure (e.g., during a vapor HF release process), or to prevent certain features from forming in steps preceding release, to name but a few. Thus, such structures are often coated with a “passivation” layer that can either remain on the structures or be removed. Typical passivation layers for MEMS wafer fabrication include an oxide layer optionally formed on a nitride layer. Passivation layers may be particularly useful for MEMS structures that are exposed to an external environment, such as, for example, MEMS microphone diaphragms.

U.S. Pat. Nos. 6,194,722, 6,274,462, 7,075,081, 7,320,896, 7,382,515, 5,817,572, 6,747,338, 6,730,591, 6,724,967, 6,887,391 and United Stated Publication No. 2008/0226929, each of which is hereby incorporated herein by reference, describe the use of silicon nitrides for etch stop in certain MEMS fabrication processes.

### SUMMARY

Embodiments include a MEMS fabrication process that includes forming a silicon-rich nitride material layer via low-pressure chemical vapor deposition (LPCVD), forming a sacrificial material layer above the LPCVD silicon-rich nitride material layer from a material that is susceptible to vapor HF etchant, forming MEMS device structures including a releasable structure above the sacrificial material layer, and removing the sacrificial material layer using a vapor HF etchant to release the releasable structure, wherein the LPCVD silicon-rich nitride material layer acts as an etch stop layer during removal of the sacrificial material layer.

The sacrificial material layer may include an oxide material. The MEMS device structures may include polysilicon. The releasable structure may include a diaphragm for a MEMS microphone, a proof mass for a MEMS accelerometer, a resonator shuttle for a MEMS gyroscope, a suspended encapsulation layer, or other releasable structure. The LPCVD silicon-rich nitride material layer may include a combination of stoichiometric silicon nitride and silicon-rich silicon nitride. The LPCVD silicon-rich nitride material layer may be formed at a temperature between around 650-900 degrees C. Forming the LPCVD silicon-rich nitride material layer may include depositing a LPCVD silicon-rich nitride material and patterning the deposited LPCVD silicon-rich nitride material. The LPCVD silicon-rich nitride material layer may be formed above a material that is susceptible to vapor HF etchant, in which case the LPCVD silicon-rich nitride material layer protects such material during removal of the sacrificial material layer.

Embodiments also include MEMS devices formed by the above-mentioned fabrication processes using silicon-rich nitride as an etch stop for vapor HF etching.

Embodiments may also include a MEMS fabrication process that includes partially or completely fabricating a MEMS device and forming a silicon-rich nitride material layer onto the MEMS device via low-pressure chemical vapor deposition (LPCVD) for passivation of the MEMS device.

The LPCVD silicon-rich nitride material layer may be an electrical passivation layer in a fully formed MEMS device, a top passivation layer in a fully formed device, a passivation layer for release of a releasable structure, or a passivation layer to prevent unwanted features from forming in steps preceding release of a releasable structure.

Embodiments may also include MEMS devices formed by the above-mentioned fabrication processes using silicon-rich nitride for passivation.

### BRIEF DESCRIPTION OF THE DRAWINGS

The foregoing and advantages of the invention will be appreciated more fully from the following further description thereof with reference to the accompanying drawings wherein:

FIG. 1 is a schematic diagram showing a MEMS device wafer including a silicon-rich nitride etch stop layer prior to etching, in accordance with one exemplary embodiment of the present invention;

FIG. 2 is a schematic diagram showing the MEMS device wafer of FIG. 1 after vapor HF etching, in accordance with one exemplary embodiment of the present invention;

FIG. 3 is a process flow diagram using silicon-rich nitride for etch stop during MEMS device fabrication, in accordance with one exemplary embodiment of the present invention;

FIG. 4 is a process flow diagram using silicon-rich nitride for etch stop during MEMS device fabrication, in accordance with another exemplary embodiment of the present invention; and

FIG. 5 is a schematic diagram showing a silicon-rich nitride passivation layer formed on exposed surfaces of the device shown in FIG. 2, in accordance with an exemplary embodiment of the present invention.

It should be noted that the foregoing figures and the elements depicted therein are not necessarily drawn to consistent scale or to any scale. Unless the context otherwise suggests, like elements are indicated by like numerals.

### DETAILED DESCRIPTION OF SPECIFIC EMBODIMENTS

Definitions. As used in this description and the accompanying claims, the following terms shall have the meanings indicated, unless the context otherwise requires:

A “silicon-rich nitride” is a silicon nitride material that has a ratio of silicon to nitrogen greater than the typical stoichiometric silicon nitride ratio of about 3:4.

A “layer” of material can be a contiguous or non-contiguous layer of material. A layer of material may be deposited and then patterned into various configurations or structures.

Embodiments of the present invention use a thin silicon-rich nitride film (e.g., having a thickness in the range of around 100A to 10000A) deposited using low-pressure chemical vapor deposition (LPCVD) for etch stop during vapor HF etching in various MEMS wafer fabrication processes and devices. The LPCVD silicon-rich nitride film may replace, or be used in combination with, a LPCVD stoichiometric nitride layer in many existing MEMS fabrication processes and devices. The LPCVD silicon-rich nitride film is deposited at high temperatures (e.g., typically around 650-900 degrees C.). Such a LPCVD silicon-rich nitride film is generally denser and has enhanced etch selectivity to vapor HF and other harsh chemical environments compared to stoichiometric silicon nitride and PECVD (plasma enhanced chemical vapor deposition) silicon-rich nitrides and therefore a thinner layer typically can be used as an embedded etch stop layer in various MEMS wafer fabrication processes and devices and particularly for vapor HF etching processes, saving time and money in the fabrication process.

In one exemplary embodiment, a LPCVD silicon-rich nitride material layer may be formed (e.g., by depositing a layer of silicon-rich nitride through a LPCVD process and patterning the deposited layer of silicon-rich nitride) on a MEMS device so as to partially or fully cover various underlying structures. A second material layer (e.g., an oxide material layer) may be formed above the LPCVD silicon-rich nitride material layer. The second material layer subsequently may be etched via vapor HF etching, with the LPCVD silicon-rich nitride material layer acting as an etch stop layer during the vapor HF etching in order to protect structures underlying the LPCVD silicon-rich nitride material layer.

In certain embodiments, the second material layer may be a sacrificial material layer (e.g., a silicon oxide layer) supporting various device structures (e.g., including fixed and/or releasable structures such as a MEMS microphone diaphragm, a MEMS accelerometer proof mass, a MEMS gyroscope resonator shuttle, which may be formed from a polysilicon material). The sacrificial material layer may be partially or fully removed via vapor HF etching process, for example, to release a releasable MEMS structure, with the LPCVD silicon-rich nitride material layer acting as an etch stop layer during the vapor HF etching process in order to protect structures underlying the LPCVD silicon-rich nitride material layer. After such removal of the sacrificial material layer, the LPCVD silicon-rich nitride material layer may be left on the MEMS device or may be removed.

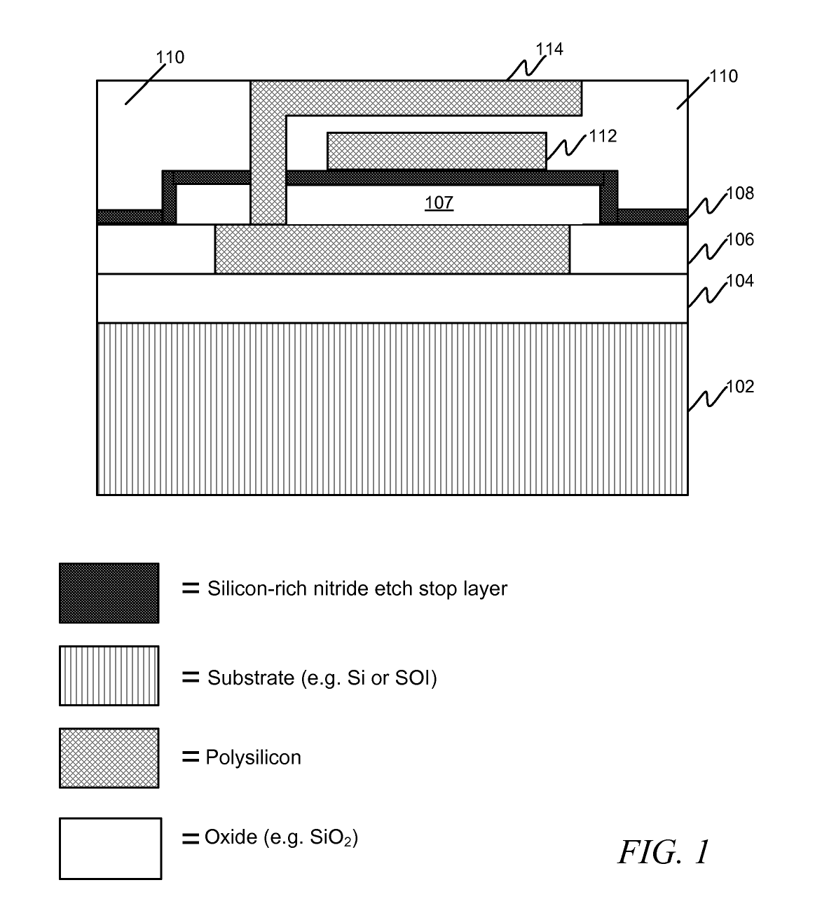

FIG. 1 is a schematic diagram showing a MEMS device wafer including a silicon-rich nitride etch stop layer prior to etching, in accordance with one exemplary embodiment of the present invention. Here, the MEMS device includes a bottom silicon substrate layer 102, an oxide layer 104 on the silicon substrate layer 102, a layer 106 on the oxide layer 104 including a conductive polysilicon electrode/runner (highlighted with cross-hatching) surrounded by oxide, an oxide layer 107 covering the electrode/runner, a LPCVD silicon-rich nitride etch stop layer 108 atop portions of layers 106 and 107, a polysilicon electrode 112 atop a portion of the LPCVD silicon-rich nitride etch stop layer 108, and a releasable polysilicon structure 114 extending through layers 108 and 107 to connect with the polysilicon electrode/runner of layer 106 and supported by a sacrificial oxide material 110 that also covers the electrode 112. During fabrication, the LPCVD silicon-rich nitride etch stop layer 108 is patterned to allow formation of the releasable polysilicon structure 114.

The sacrificial oxide material 110 is then removed via vapor HF etching. In this regard, the releasable polysilicon structure 114 typically includes a number of releasing holes (not shown) to allow the vapor HF to flow through to the underlying sacrificial oxide material 110.

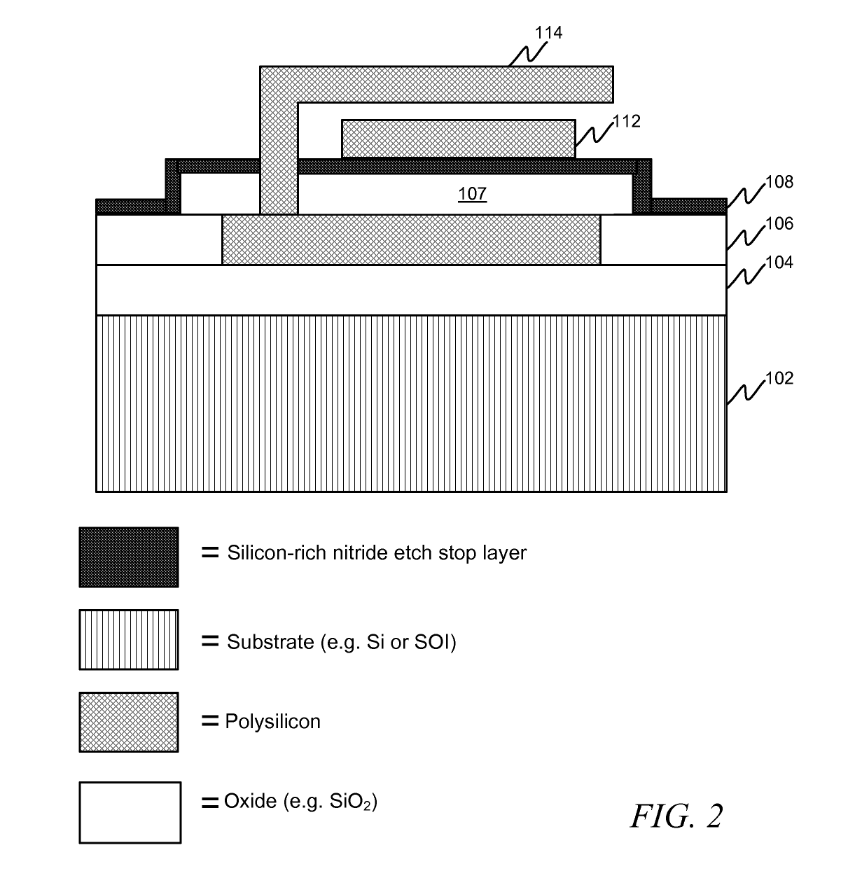

FIG. 2 is a schematic diagram showing the MEMS device wafer of FIG. 1 after vapor HF etching, in accordance with one exemplary embodiment of the present invention. The LPCVD silicon-rich nitride layer 108 protects the underlying structures 102, 104, 106, and 107 during removal of the sacrificial oxide material 110.

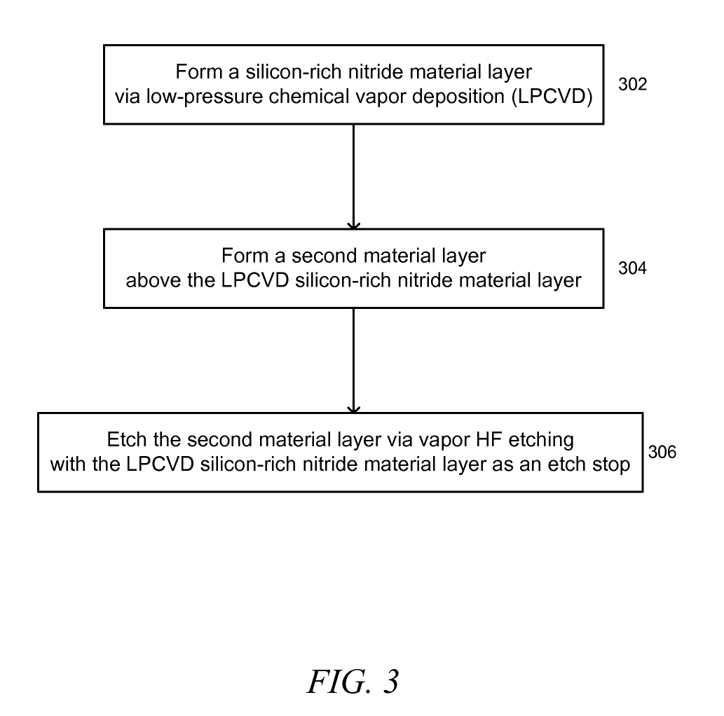

FIG. 3 is a process flow diagram using silicon-rich nitride for etch stop during MEMS device fabrication, in accordance with one exemplary embodiment of the present invention. In block 302, a silicon-rich nitride material layer is formed via low-pressure chemical vapor deposition (LPCVD). In block 304, a second material layer is formed above the LPCVD silicon-rich nitride material layer. In block 306, the second material layer is etched via vapor HF etching with the LPCVD silicon-rich nitride material layer as an etch stop.

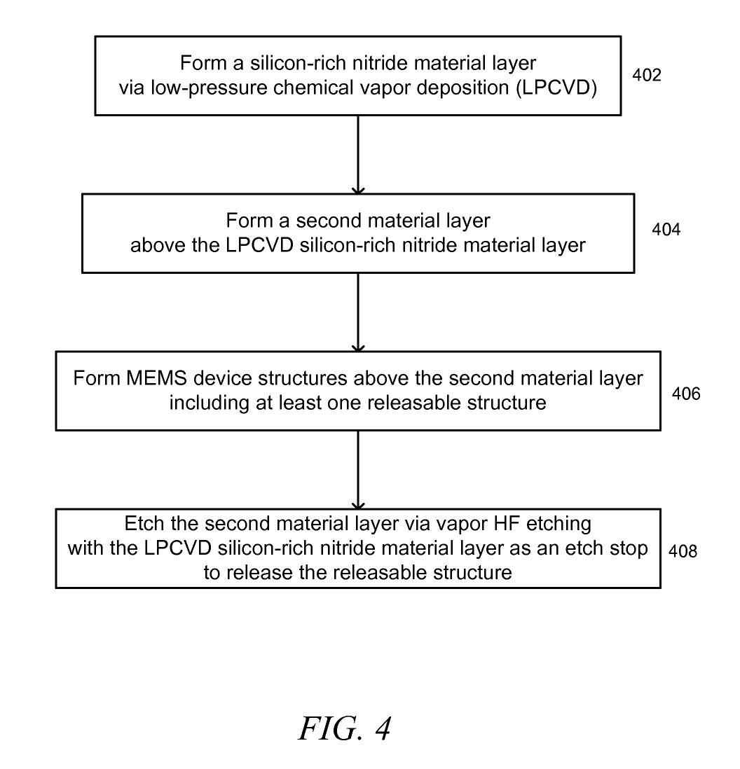

FIG. 4 is a process flow diagram using silicon-rich nitride for etch stop during MEMS device fabrication, in accordance with another exemplary embodiment of the present invention. In block 402, a silicon-rich nitride material layer is formed via low-pressure chemical vapor deposition (LPCVD). In block 404, a second material layer is formed above the LPCVD silicon-rich nitride material layer. In block 406, MEMS device structures including at least one releasable structure are formed above the second material layer. In block 408, the second material layer is etched via vapor HF etching with the LPCVD silicon-rich nitride material layer as an etch stop to release the releasable structure.

In another exemplary embodiment, a LPCVD silicon-rich nitride material layer may be deposited onto a partially or completely formed MEMS device for passivation. For example, the LPCVD silicon-rich nitride material layer may be used for electrical passivation in the fully formed device, as a top passivation layer in the fully formed device, for passivation during release of a releasable structure (e.g., during a vapor HF release process), or to prevent certain features from forming in steps preceding release, to name but a few. In certain embodiments, the LPCVD silicon-rich nitride material layer is formed at a temperature between around 650-900 degrees C.

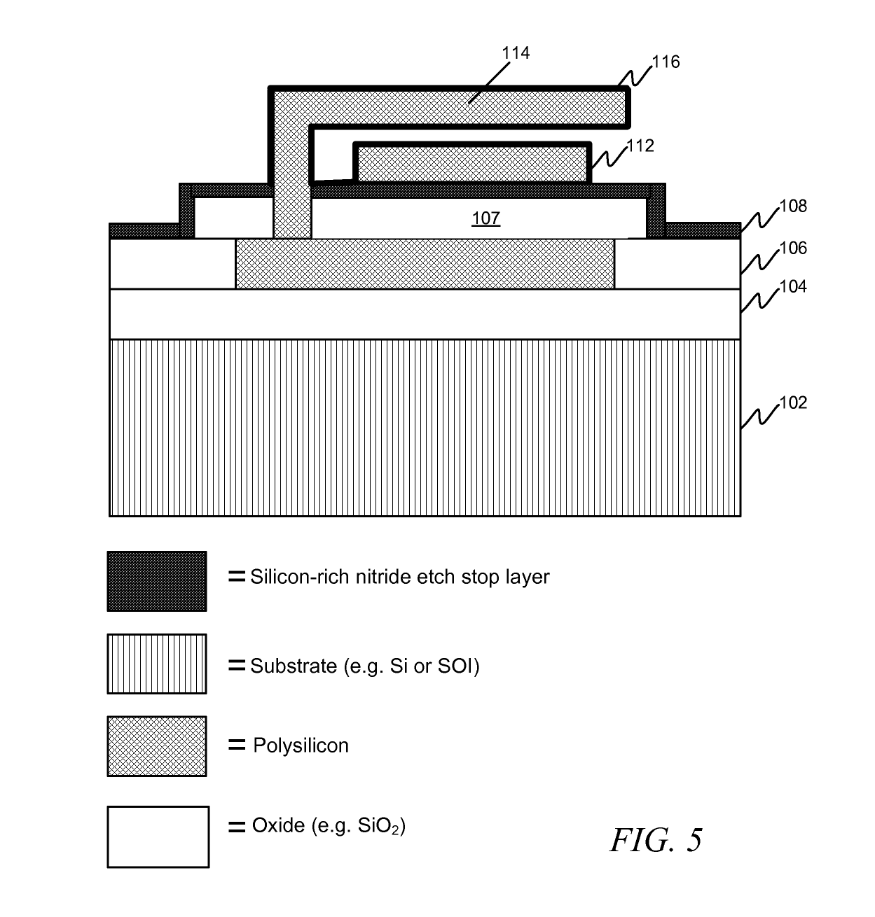

FIG. 5 is a schematic diagram showing a silicon-rich nitride passivation layer 116 formed on exposed surfaces of the device shown in FIG. 2, in accordance with an exemplary embodiment of the present invention. Such a passivation layer might be used, for example, on surfaces that are exposed to an external environment such as, for example, the diaphragm of a MEMS microphone or MEMS pressure sensor.

Thus, embodiments of the present invention include a MEMS device (e.g., a MEMS microphone, accelerometer, gyroscope, pressure sensor, optical device, etc.) including one or more LPCVD silicon-rich nitride material layers for etch stop and/or passivation in the presence of vapor HF.

Embodiments of the present invention also include a MEMS fabrication process in which one or more LPCVD silicon-rich nitride material layers are formed for etch stop and/or passivation in the presence of vapor HF. For example, a LPCVD silicon-rich nitride etch stop layer may be used during release of a releasable MEMS structure such as during removal of a sacrificial oxide material using vapor HF etching.

The present invention may be embodied in other specific forms without departing from the true scope of the invention. Any references to the “invention” are intended to refer to exemplary embodiments of the invention and should not be construed to refer to all embodiments of the invention unless the context otherwise requires. The described embodiments are to be considered in all respects only as illustrative and not restrictive.

What is claimed is:

1. A MEMS fabrication process comprising:
forming a silicon-rich nitride material layer via low-pressure chemical vapor deposition (LPCVD);
forming a sacrificial material layer above the LPCVD silicon-rich nitride material layer from a material that is susceptible to vapor HF etchant;
forming MEMS device structures including a releasable structure above the sacrificial material layer; and
removing the sacrificial material layer using a vapor HF etchant to release the releasable structure, wherein the LPCVD silicon-rich nitride material layer acts as an etch stop layer during removal of the sacrificial material layer.

2. A MEMS fabrication process according to claim 1, wherein the sacrificial material layer includes an oxide material.

3. A MEMS fabrication process according to claim 1, wherein the MEMS device structures include polysilicon.

4. A MEMS fabrication process according to claim 1, wherein the releasable structure includes at least one of:
a diaphragm for a MEMS microphone;
a proof mass for a MEMS accelerometer;
a resonator shuttle for a MEMS gyroscope; and
a suspended encapsulation layer.

5. A MEMS fabrication process according to claim 1, wherein the LPCVD silicon-rich nitride material layer includes a combination of stoichiometric silicon nitride and silicon-rich silicon nitride.

6. A MEMS fabrication process according to claim 1, wherein the LPCVD silicon-rich nitride material layer is formed at a temperature between around 650-900 degrees C.

7. A MEMS fabrication process according to claim 1, wherein forming the LPCVD silicon-rich nitride material layer includes depositing a LPCVD silicon-rich nitride material and patterning the deposited LPCVD silicon-rich nitride material.

8. A MEMS fabrication process according to claim 1, wherein the LPCVD silicon-rich nitride material layer is formed above a material that is susceptible to vapor HF etchant, and wherein the LPCVD silicon-rich nitride material layer protects such material during removal of the sacrificial material layer.

9. A MEMS device formed by the process of:
forming a silicon-rich nitride material layer via low-pressure chemical vapor deposition (LPCVD);
forming a sacrificial material layer above the LPCVD silicon-rich nitride material layer from a material that is susceptible to vapor HF etchant;
forming MEMS device structures including a releasable structure above the sacrificial material layer; and
removing the sacrificial material layer using a vapor HF etchant to release the releasable structure, wherein the LPCVD silicon-rich nitride material layer acts as an etch stop layer during removal of the sacrificial material layer.

10. A MEMS device according to claim 9, wherein the sacrificial material layer includes an oxide material.

11. A MEMS device according to claim 9, wherein the MEMS device structures include polysilicon.

12. A MEMS device according to claim 9, wherein the releasable structure includes at least one of:
a diaphragm for a MEMS microphone;
a proof mass for a MEMS accelerometer;
a resonator shuttle for a MEMS gyroscope; and
a suspended encapsulation layer.

13. A MEMS device according to claim 9, wherein the LPCVD silicon-rich nitride material layer includes a combination of stoichiometric silicon nitride and silicon-rich silicon nitride.

14. A MEMS device according to claim 9, wherein the LPCVD silicon-rich nitride material layer is formed at a temperature between around 650-900 degrees C.

15. A MEMS device according to claim 9, wherein forming the LPCVD silicon-rich nitride material layer includes depositing a LPCVD silicon-rich nitride material and patterning the deposited LPCVD silicon-rich nitride material.

16. A MEMS device according to claim 9, wherein the LPCVD silicon-rich nitride material layer is formed above a material that is susceptible to vapor HF etchant, and wherein the LPCVD silicon-rich nitride material layer protects such material during removal of the sacrificial material layer.

17. A MEMS fabrication process comprising:
partially or completely fabricating a MEMS device; and
forming a silicon-rich nitride material layer onto the MEMS device via low-pressure chemical vapor deposition (LPCVD) for passivation of the MEMS device.

18. A MEMS fabrication process according to claim 17, wherein the LPCVD silicon-rich nitride material layer is at least one of:
an electrical passivation layer in a fully formed MEMS device;
a top passivation layer in a fully formed device;
a passivation layer for release of a releasable structure; and
a passivation layer to prevent unwanted features from forming in steps preceding release of a releasable structure.

19. A MEMS device formed by the process comprising:
partially or completely fabricating a MEMS device; and
forming a silicon-rich nitride material layer onto the MEMS device via low-pressure chemical vapor deposition (LPCVD) for passivation of the MEMS device.

20. A MEMS device according to claim 19, wherein the LPCVD silicon-rich nitride material layer is at least one of:
an electrical passivation layer in a fully formed MEMS device;
a top passivation layer in a fully formed device;
a passivation layer for release of a releasable structure; and
a passivation layer to prevent unwanted features from forming in steps preceding release of a releasable structure.
